(19) United States
(12) Patent Application Publication
(10) Pub. No.: US 2021/0343979 A1
(43) Pub. Date: Nov. 4, 2021

(54) DISPLAY SUBSTRATE AND MANUFACTURING METHOD THEREOF, DISPLAY MODULE, AND DISPLAY DEVICE

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Lian Xiang, Beijing (CN); Yan Yang, Beijing (CN)

(21) Appl. No.: 17/280,678

(22) PCT Filed: May 19, 2020
(86) PCT No.: PCT/CN2020/091051

§ 371 Date: Mar. 26, 2021

(30) Foreign Application Priority Data
May 28, 2019 (CN) 201910452099.1

(51) Int. Cl. H01L 51/52; H01L 51/56

(52) U.S. Cl. CPC H01L 51/5246; H01L 51/56; H01L 51/529; H01L 51/5281

(57) ABSTRACT

Embodiments of the present disclosure provide a display substrate, including: a base substrate; a light emitting device on the base substrate; an encapsulating layer on the base substrate and configured to encapsulate the light emitting device; and an anti-vibration layer on the base substrate. An orthographic projection of the anti-vibration layer on the base substrate has no overlap with an orthographic projection of the light emitting device on the base substrate. The orthographic projection of the anti-vibration layer on the base substrate has an overlap with an orthographic projection of the encapsulating layer on the base substrate, and the overlap is smaller than the orthographic projection of the anti-vibration layer on the base substrate in area. The embodiments of the present disclosure further provide a manufacturing method of a display substrate, a display module, and a display device.

### CROSS-REFERENCE TO RELATED APPLICATION

This application is a Section 371 National Stage Application of International Application PCT/CN2020/091051, and claims priority to Chinese Patent Application No. 201910452099.1 filed on May 28, 2019, which is incorporated herein by reference in its entirety.

### TECHNICAL FIELD

The present disclosure relates to the field of display technology, and in particular to a display substrate and a manufacturing method thereof, a display module, and a display device.

### BACKGROUND

With the advent of the automotive multimedia era, market demand for vehicle DVD, VCD, TV, and other media systems is growing. Such systems require specialized vehicle displays. While a vehicle is driving, such displays vibrate with bumps of the vehicle. Long-term vibration not only affects the display's use, but can also cause damage to the display and reduce its service life. Moreover, in a severe vibration environment, Organic Light Emitting Diode (OLED) displays encapsulated using traditional encapsulating methods may have various undesirable problems caused by cracks.

### SUMMARY

In a first aspect, the embodiments of the present disclosure provide a display substrate, including: a base substrate; a light emitting device on the base substrate; an encapsulating layer disposed on the base substrate and configured to encapsulate the light emitting device; and an anti-vibration layer on the base substrate; wherein an orthographic projection of the anti-vibration layer on the base substrate does not overlap with an orthographic projection of the light emitting device on the base substrate; and wherein the orthographic projection of the anti-vibration layer on the base substrate has an overlap with an orthographic projection of the encapsulating layer on the base substrate, and an area of the overlap is smaller than an area of the orthographic projection of the anti-vibration layer on the base substrate.

In an exemplary embodiment, the anti-vibration layer is continuously arranged.

In another exemplary embodiment, the anti-vibration layer is discontinuously arranged and includes two or more discontinuous portions, and an orthographic projection of an edge position of the encapsulating layer on the base substrate is located in an orthographic projection of a spacing between the two or more discontinuous portions on the base substrate.

In an exemplary embodiment, the display substrate further includes an anti-crack layer and a plurality of water and oxygen barrier layers on the base substrate; the water and oxygen barrier layers are arranged between the light emitting device and the anti-vibration layer; the anti-crack layer is arranged away from the anti-vibration layer, and an orthographic projection of the anti-crack layer on the base substrate does not overlap with the orthographic projection of the encapsulating layer on the base substrate.

In an exemplary embodiment, an area of an oethographic projection of the anti-vibration layer on the base substrate is greater than an area of an orthographic projection of the water and oxygen barrier layers on the base substrate.

In an exemplary embodiment, the water and oxygen barrier layers, the anti-vibration layer and the anti-crack layer contain an organic material.

In a second aspect, an embodiment of the present disclosure provides a display module, including the display substrate described in any embodiment in the first aspect.

In an exemplary embodiment, the display module further includes: a polarizer and a cover plate that are disposed on the display substrate in sequence; a heat-dissipating and shielding layer on a side of the display substrate away from the polarizer; and an anti-vibration film layer on a side of the heat-dissipating and shielding layer away from the display substrate.

In another exemplary embodiment, the display module further includes: a polarizer and a cover plate that are disposed on the display substrate in sequence; a heat-dissipating and shielding layer on a side of the display substrate away from the polarizer; and an anti-vibration film layer, wherein a structure formed by the anti-vibration film layer and the cover plate covers the polarizer, the display substrate and the heat-dissipating and shielding layer.

In a third aspect, an embodiment of the present disclosure provides a display device, including the display module described in any embodiment in the second aspect.

In another aspect, an embodiment of the present disclosure further provides a method of manufacturing the display substrate as described in the first aspect, wherein the anti-crack layer further includes a first part and a second part on the first part, and the method includes: coating a layer of organic material on the base substrate, wherein the light emitting device and the second part of the anti-crack layer have been formed on the base substrate; exposing the layer of organic material by using a mask with patterns of the water and oxygen barrier layers, the anti-vibration layer and the anti-crack layer; and developing and curing the exposed layer of organic material, so as to form the water and oxygen barrier layers, the anti-vibration layer and the first part of the anti-crack layer.

### BRIEF DESCRIPTION OF THE DRAWINGS

By reading the detailed description of the exemplary implementations below, various other advantages and benefits will become clear to those ordinary skilled in the art. The drawings are only used for the purpose of showing alternative implementations, and are not considered as a limitation to the embodiments of the present disclosure. Throughout the drawings, the same reference symbols are used to denote the same components. In the drawings:

FIG. 1 shows a schematic structural diagram of a display substrate according to an exemplary embodiment of the present disclosure;

FIG. 2 shows a schematic structural diagram of a display substrate according to another exemplary embodiment of the present disclosure;

FIG. 3 shows a manufacturing flowchart of water and oxygen barrier layers, an anti-vibration layer and an anti-crack layer in a display substrate according to an exemplary embodiment of the present disclosure;

FIG. 4 shows a schematic structural diagram of a display module according to an exemplary embodiment of the present disclosure; and

FIG. 5 shows a schematic structural diagram of a display module according to another exemplary embodiment of the present disclosure.

FIG. 6 shows a schematic top view of a display substrate according to an exemplary embodiment of the present disclosure;

FIG. 7 shows a schematic top view of a display substrate according to another exemplary embodiment of the present disclosure.

### DETAILED DESCRIPTION OF EMBODIMENTS

Exemplary embodiments of the present disclosure will be described below in more detail with reference to the drawings. Although the exemplary embodiments of the present disclosure are shown in the drawings, it should be understood that the present disclosure may be implemented in various forms and should not be limited by the embodiments described herein. On the contrary, these embodiments are provided to enable a more thorough understanding of the present disclosure and to fully convey the scope of the present disclosure to those skilled in the art.

Those skilled in the art may understand that unless specifically stated, the singular forms “a”, “an”, “said” and “the” used herein may also include the plural forms. It should be further understood that the word “comprising” or “including” used in the specification of the present disclosure refers to the presence of the described features, integers, steps, operations, elements and/or components, but does not exclude the presence or addition of one or more other features, integers, steps, operations, elements, components, and/or groups thereof. It should be understood that when an element is referred to as being “connected” to another element, it may be directly connected to the other element, or there may be an intermediate element. In addition, “connection” as used herein may include wireless connection. The expression “and/or” as used herein includes all or any unit and all combinations of one or more associated listed items.

Those skilled in the art may understand that unless otherwise defined, all terms (including technical and scientific terms) used herein have the same meaning as those generally understood by those ordinary skilled in the art to which this application belongs. It should also be understood that terms such as those defined in a general dictionary should be understood to have a meaning consistent with the meaning in the context of the related art, and unless specifically defined as here, it would not be interpreted in an idealized or overly formal sense.

In order to solve various undesirable problems caused by cracks in the display substrate in the related art under severe vibration environment, the present disclosure provides a new design of display substrate.

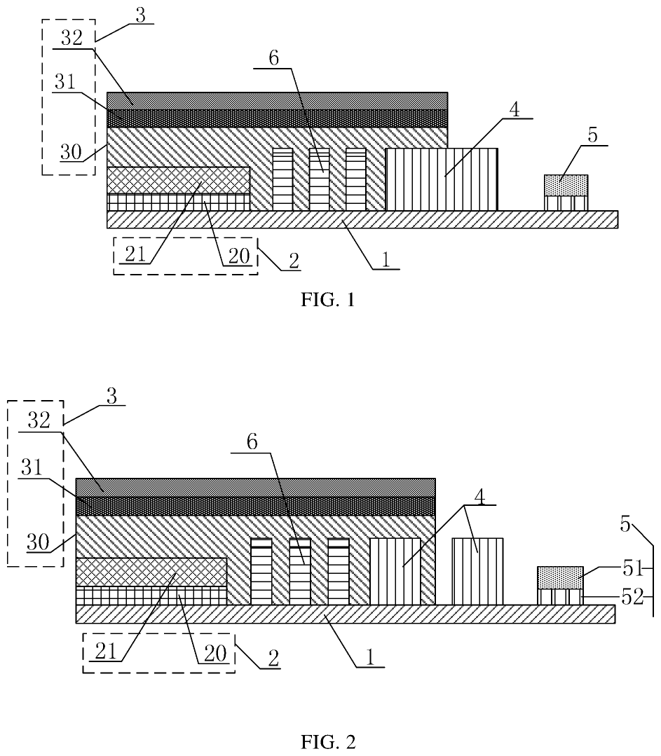

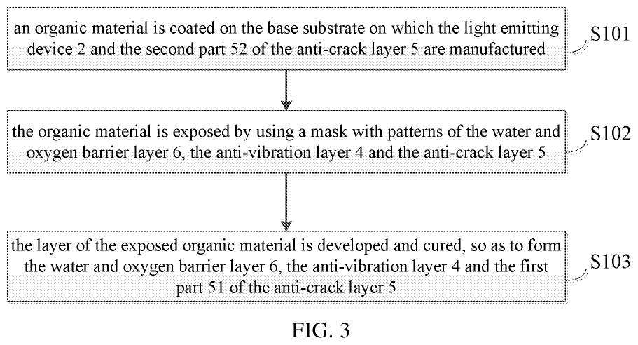

In a first aspect, FIGS. 1 and 2 show a display substrate provided by an exemplary embodiment of the present disclosure. As shown in FIGS. 1 and 2, the display substrate includes a base substrate 1, a light emitting device 2 on the base substrate 1, and an encapsulating layer 3 on the base substrate 1 that is configured to encapsulate the light emitting device 2. Specifically, the light emitting device 2 includes a light emitting layer 20 on the base substrate 1 and a cathode 21 on the light emitting layer 20. The encapsulating layer 3 includes a first inorganic encapsulating layer 30, an organic encapsulating layer 31 and a second inorganic encapsulating layer 32 sequentially arranged on the cathode 21. The light emitting device 2 further includes an anode (not shown). The specific arrangement of the light emitting device 2 may be the same as that in the related art, which will not be repeated here. In addition, it should be noted that FIG. 1 only shows the encapsulating layer 3 includes two inorganic encapsulating layers and one organic encapsulating layer. The encapsulating layer 3 can include additional inorganic encapsulating layers and organic encapsulating layers overlapped alternately. The specific position and material selection of the encapsulating layer 3 may be the same as those in the related art, which will not be repeated here.

As shown in FIGS. 1 and 2, the display substrate provided by the exemplary embodiment of the present disclosure further includes an anti-vibration layer 4 on the base substrate 1. An orthographic projection of the anti-vibration layer 4 on the base substrate 1 has no overlap with an orthographic projection of the light emitting device 2 on the base substrate 1. The orthographic projection of the anti-vibration layer 4 on the base substrate 1 has an overlap with an orthographic projection of the encapsulating layer 3 on the base substrate 1, and the overlap is smaller than the orthographic projection of the anti-vibration layer 4 on the base substrate 1 in area. That is, in the embodiment of the present disclosure, at least a part of the anti-vibration layer 4 is covered by the first inorganic encapsulating layer 30, and the other part of the anti-vibration layer 4 is not covered by the first inorganic encapsulating layer 30. The anti-vibration layer 4 provided in the embodiment of the present disclosure prevents or helps to prevent the display substrate from being damaged due to stress caused by environmental vibration during use, and mainly serves as a buffer.

According to the embodiment of the present disclosure, the display substrate includes the anti-vibration layer 4, the orthographic projection of the anti-vibration layer 4 on the base substrate 1 has no overlap with the orthographic projection of the light emitting device 2 on the base substrate 1; the orthographic projection of the anti-vibration layer 4 on the base substrate 1 has an overlap with the orthographic projection of the encapsulating layer 3 on the base substrate 1, and the overlap is smaller than the orthographic projection of the anti-vibration layer 4 on the base substrate 1 in area. This arrangement of the anti-vibration layer 4 may enhance an overall anti-vibration performance of the display substrate, and effectively avoid an occurrence of various undesirable problems due to cracks caused by vibration of the display substrate in a severe vibration environment. In addition, when the display substrate is applied to a vehicle display screen, it may cope with the vibration environment encountered in the driving of the vehicle, so as to ensure a normal operation of the display screen under a severe vibration driving condition, thereby ensuring the safety of the driver.

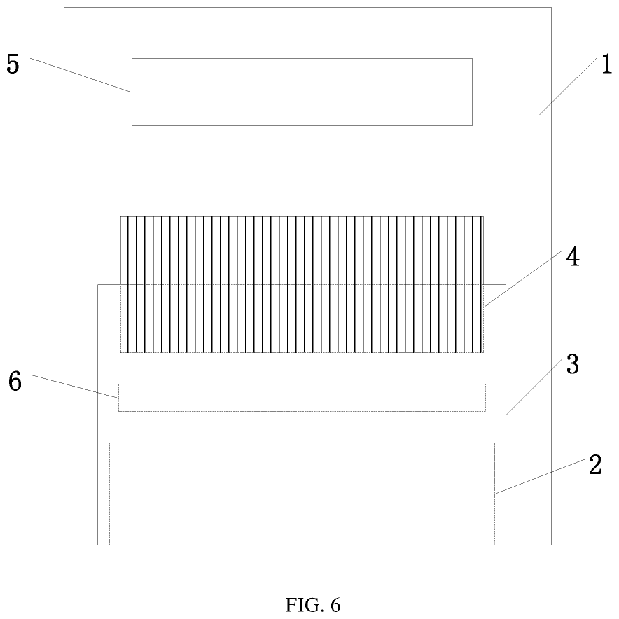

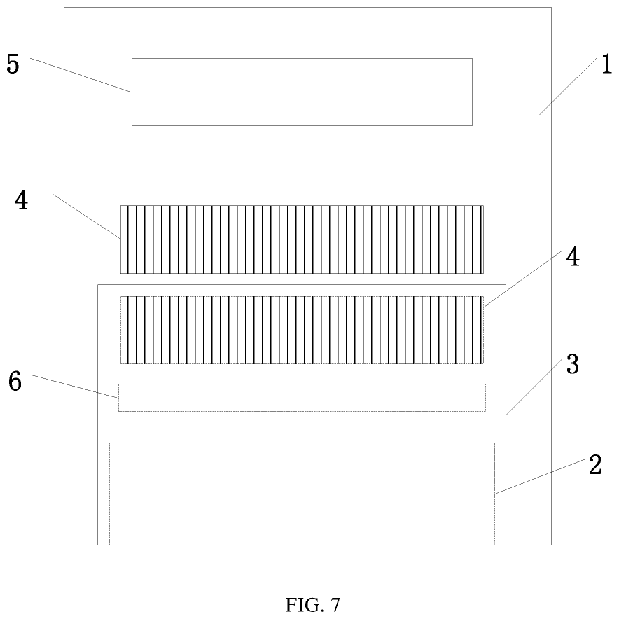

In some embodiments, in order to make a structure of the display substrate provided by the embodiments of the present disclosure more diverse, and considering the influence of the position and size of the anti-vibration layer 4 on the anti-vibration performance, the present disclosure provides two specific exemplary embodiments. In one exemplary embodiment, as shown in FIG. 1 and FIG. 6, the anti-vibration layer 4 is continuously arranged, that is, the anti-vibration layer 4 has an integral structure continuously and uninterruptedly formed on the base substrate 1. In the other exemplary embodiment, as shown in FIG. 2 and FIG. 7, the anti-vibration layer 4 is discontinuously arranged, that is, a split structure may be employed, and the anti-vibration layer 4 has two or more discontinuous portions on the base substrate 1.

For example, as shown in FIG. 2 and FIG. 7, when the anti-vibration layer 4 is discontinuously arranged, an orthographic projection of an edge position of the encapsulating layer 3 on the base substrate 1 is located in an orthographic projection of a discontinuity position between two or more discontinuous portions on the base substrate 1, that is, the discontinuity position corresponds to the edge position of the encapsulating layer 3 The anti-vibration layer 4 can be provided with a plurality of discontinuity positions. The specific discontinuity positions may be designed according to actual needs and a size of a display substrate bezel area. The greater the number of discontinuity positions, the larger the bezel must be.

It should be noted that the arrangement of the anti-vibration layer 4 shown in FIG. 1 not only increases the size of the anti-vibration layer 4 and enhances vibration resistance, but also increases a design controllability and an adjustment of the device process, thereby achieving advantages of simplification in process and design. The arrangement of the anti-vibration layer 4 shown in FIG. 2 may effectively reduce an impact force caused by the vibration in structure, but there are certain difficulties in design and process.

As shown in FIG. 1 and FIG. 2, the display substrate provided by the exemplary embodiments of the present disclosure may further include an anti-crack layer 5 and a plurality of water and oxygen barrier layers 6 on the base substrate 1. FIG. 6 and FIG. 7 use a block 6 to indicate the water and oxygen barrier layer 6, however, this does not mean that there is only one water and oxygen barrier layers 6, rather, there are a plurality of water and oxygen barrier layers 6. The water and oxygen barrier layers 6 are arranged between the light emitting device 2 and the anti-vibration layer 4, and an orthographic projection of the water and oxygen barrier layers 6 on the base substrate 1 is located in the orthographic projection of the encapsulating layer 3 on the base substrate 1. The anti-crack layer 5 is arranged away from the anti-vibration layer 4, and an orthographic projection of the anti-crack layer 5 on the base substrate 1 has no overlap with the orthographic projection of the encapsulating layer 3 on the base substrate 1. Since the display substrate of the embodiments of the present disclosure is provided with the anti-crack layer 5 and the water and oxygen barrier layers 6 in addition to the anti-vibration layer 4, the display substrate may be vibration-proof, crack-proof and water-proof, which further enhances the safety performance of the display substrate, increases the service life, and enhances market competitiveness.

Specifically, the water and oxygen barrier layers 6 are mainly used to prevent water and oxygen from eroding the display area of the display substrate. The water and oxygen barrier layers 6 is spaced from the anti-vibration layer 4 at a certain distance, so that the water and oxygen barrier layers 6 may well meet the requirements of blocking water and oxygen. The embodiment of the present disclosure does not limit the specific position and number of the water and oxygen barrier layers 6, and the water and oxygen barrier layers 6 may be designed according to the size of the display substrate bezel area. In addition, an organic layer may be further provided above the water and oxygen barrier layers 6 shown in FIGS. 1 and 2 so as to fill a fault gap. The specific arrangement of the water and oxygen barrier layers 6 in the embodiments of the present disclosure is similar to that in the related art, which will not be repeated here.

Specifically, the anti-crack layer 5 is located at an edge of the display substrate 1, and a certain burning area for laser cutting needs to be reserved at an outermost edge of the display substrate 1. The anti-crack layer 5 is used to prevent cracks of the display area caused by the laser cutting. In specific implementation, as shown in FIG. 2, the anti-crack layer 5 may further include a first part 51 and a second part 52. The first part 51 of the anti-crack layer 5 is made of an organic material, and the second part 52 of the anti-crack layer 5 is made of an inorganic material. The specific arrangement of the anti-crack layer 5 in the embodiments of the present disclosure is similar to that in the related art, which will not be repeated here.

In some embodiments, the anti-vibration layer 4 has a volume greater than that of the water and oxygen barrier layers 6. This arrangement can further enhance the anti-vibration effect of the display substrate.

In some embodiments, the water and oxygen barrier layers 6, the anti-vibration layer 4 and the anti-crack layer 5 contain an organic material. The use of the organic material may manufacture thicker water and oxygen barrier layers 6, anti-vibration layer 4 and anti-crack layer 5 with lower production cost, thereby enhancing market competitiveness.

In addition, since the water and oxygen barrier layers 6, the anti-vibration layer 4 and the anti-crack layer 5 contain an organic material, an organic film layer may be coated to simultaneously manufacture the water and oxygen barrier layers 6, the anti-vibration layer 4 and the anti-crack layer 5. It is only necessary to design patterns of the water and oxygen barrier layers 6, the anti-vibration layer 4 and the anti-crack layer 5 on one mask, without additional process and additional cost of the mask.

Specifically, in the case where the second part 52 of the anti-crack layer 5 is manufactured, as shown in FIG. 3, the production method of the water and oxygen barrier layers 6, the anti-vibration layer 4 and the anti-crack layer 5 in the display substrate includes the following steps.

S101: an organic material is coated on the base substrate on which the light emitting device 2 and the second part 52 of the anti-crack layer 5 are manufactured.

S102: the organic material is exposed by using a mask with patterns of the water and oxygen barrier layers 6, the anti-vibration layer 4 and the anti-crack layer 5.

S103: the layer of the exposed organic material is developed and cured, so as to form the water and oxygen barrier layers 6, the anti-vibration layer 4 and the first part 51 of the anti-crack layer 5.

In a second aspect, the embodiments of the present disclosure provide a display module, including the display substrate as described in any embodiment in the first aspect. Since the display module described in the second aspect includes the display substrate described in any embodiment of the first aspect, the display module has the same beneficial effects as the display substrate described in any embodiment of the first aspect. Therefore, the beneficial effects of the display module in the second aspect will not be repeated here.

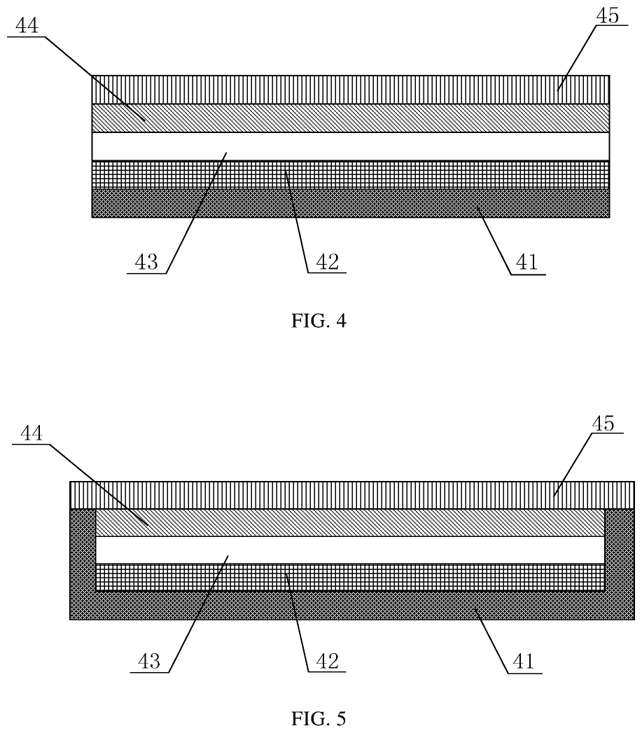

In an exemplary embodiment, as shown in FIG. 4, the display module of the embodiments of the present disclosure further includes a polarizer 44 and a cover plate 45 on the display substrate 43 in sequence, a heat-dissipating and shielding layer 42 on a side of the display substrate 43 away from the polarizer 44, and an anti-vibration film layer 41 on a side of the heat-dissipating and shielding layer 42 away from the display substrate 43. The specific arrangements of the polarizer 44 and the cover plate 45 are similar to those in the related art, which will not be repeated here.

As shown in FIG. 4, the heat-dissipating and shielding layer 42 is attached to a back of the display substrate 43 (that is, the side of the display substrate 43 away from the polarizer 44), so as to achieve light shading, buffering, heat-dissipating, shielding and other functions on the screen of the display substrate 43. In addition, the anti-vibration film layer 41 is attached to the heat-dissipating and shielding layer 42 with an adhesive material with good thermal conductivity, such as silica gel and so on, so as to improve an overall anti-vibration level of the display module and meet a working stability of the vehicle screen under a severe vibration environment.

It should be noted that the display substrate 43 in FIG. 4 may be the display substrate provided with the anti-vibration layer 4 according to any embodiment in the first aspect of the present disclosure, or it may be an ordinary display substrate in the related art without the anti-vibration layer. When the display substrate 43 is the display substrate provided with the anti-vibration layer 4 according to any embodiment in the first aspect of the present disclosure, a display module with a high anti-vibration level can be achieved under an interaction of the anti-vibration layer 4 and the anti-vibration film layer 41.

In another exemplary embodiment, as shown in FIG. 5, the display module of the embodiments of the present disclosure further includes a polarizer 44 and a cover plate 45 on the display substrate 43 in sequence, a heat-dissipating and shielding layer 42 on a side of the display substrate 43 away from the polarizer 44, and an anti-vibration film layer 41. A structure formed by the anti-vibration film layer 41 and the cover plate 45 covers the polarizer 44, the display substrate 43 and the heat-dissipating and shielding layer 42. Compared with the structure of the display module in the exemplary embodiment shown in FIG. 4, the anti-vibration film layer 41 included in the display module in the exemplary embodiment shown in FIG. 5 can also reduce a stress impact caused by left-right vibrations, thereby achieving a higher level of vibration resistance.

Specifically, the anti-vibration film layer 41 may be made of an embossed silica gel buffer material, foam, and other membrane materials with anti-vibration and buffer functions. However, for those skilled in the art, other suitable materials may also be used according to actual needs.

In a third aspect, the embodiments of the present disclosure provide a display device, including the display module as described in any embodiment in the second aspect of the present disclosure. Since the display device of the third aspect includes the display module described in any embodiment of the second aspect, the display device has the same beneficial effects as the display module described in any embodiment of the second aspect. Therefore, the beneficial effects of the display device of the third aspect will not be repeated here.

The beneficial effects obtained by applying the embodiments of the present disclosure at least include the following.

1. The display substrate provided by the embodiments of the present disclosure include an anti-vibration layer at a boundary position of the encapsulating layer, with a part thereof being covered by the encapsulating layer and the other part thereof being not covered by the encapsulating layer. This arrangement of the anti-vibration layer may enhance the overall anti-vibration performance of the display substrate, and effectively prevent the occurrence of various undesirable problems due to cracks caused by vibration of the display substrate in a severe vibration environment. In addition, when the display substrate is applied to the vehicle display screen, it may cope with the vibration environment encountered in the driving of the vehicle, so as to ensure the normal operation of the display screen under a severe vibration driving condition, thereby ensuring the safety of the driver.

2. The display substrate of the embodiments of the present disclosure is provided with the anti-crack layer and the water and oxygen barrier layers in addition to the anti-vibration layer. Therefore, the display substrate may be vibration-proof, crack-proof and water-proof, which further enhances the safety performance of the display substrate, increases the service life, and enhances the market competitiveness.

3. The display module of the embodiments of the present disclosure is attached to the back of the display substrate, so as to achieve the light shading, buffering, heat-dissipating, shielding and other functions on the screen of the display substrate. In addition, the anti-vibration film layer is attached to the heat-dissipating and shielding layer with an adhesive material with good thermal conductivity, such as silica gel and so on, so as to improve the overall anti-vibration level of the display module and meet the working stability of the vehicle screen under a severe vibration environment.

The above are only part of the embodiments of the present disclosure. It should be noted that for those ordinary skilled in the art, without departing from the principles of the present disclosure, several improvements and modification may be made. These improvements and modification should also be regarded as the scope of protection of the present disclosure.

1. A display substrate, comprising:
a base substrate;
a light emitting device on the base substrate;
an encapsulating layer disposed on the base substrate and configured to encapsulate the light emitting device; and
an anti-vibration layer on the base substrate,
wherein an orthographic projection of the anti-vibration layer on the base substrate does not overlap with an orthographic projection of the light emitting device on the base substrate; and
wherein the orthographic projection of the anti-vibration layer on the base substrate has an overlap with an orthographic projection of the encapsulating layer on the base substrate, and an area of the overlap is smaller than an area of the orthographic projection of the anti-vibration layer on the base substrate.

2. The display substrate according to claim 1, wherein the anti-vibration layer is continuously arranged.

3. The display substrate according to claim 1, wherein the anti-vibration layer is discontinuously arranged and comprises two or more discontinuous portions, and an orthographic projection of an edge position of the encapsulating layer on the base substrate is located in an orthographic projection of a spacing between the two or more discontinuous portions on the base substrate.

4. The display substrate according to claim 1, further comprising: an anti-crack layer and a plurality of water and oxygen barrier layers on the base substrate;
wherein the water and oxygen barrier layers are arranged between the light emitting device and the anti-vibration layer; and
wherein the anti-crack layer is arranged away from the anti-vibration layer, and an orthographic projection of the anti-crack layer on the base substrate does not overlap with the orthographic projection of the encapsulating layer on the base substrate.

5. The display substrate according to claim 4, wherein an area of an orthographic projection of the anti-vibration layer on the base substrate is greater than an area of an orthographic projection of the water and oxygen barrier layers on the base substrate.

6. The display substrate according to claim 4, wherein the water and oxygen barrier layers, the anti-vibration layer and the anti-crack layer comprise an organic material.

7. A display module, comprising the display substrate according to claim 1.

8. The display module according to claim 7, further comprising:
a polarizer and a cover plate that are disposed on the display substrate in sequence;
a heat-dissipating and shielding layer on a side of the display substrate away from the polarizer; and
an anti-vibration film layer on a side of the heat-dissipating and shielding layer away from the display substrate.

9. The display module according to claim 7, further comprising:
a polarizer and a cover plate that are disposed on the display substrate in sequence;
a heat-dissipating and shielding layer on a side of the display substrate away from the polarizer; and
an anti-vibration film layer, wherein a structure formed by the anti-vibration film layer and the cover plate covers the polarizer, the display substrate and the heat-dissipating and shielding layer.

10. A display device, comprising the display module according to claim 7.

11. A method of manufacturing the display substrate according to claim 6, wherein the anti-crack layer further comprises a first part and a second part on the first part, the method comprising:
coating a layer of organic material on the base substrate, wherein the light emitting device and the second part of the anti-crack layer have been formed on the base substrate;
exposing the layer of organic material by using a mask with patterns of the water and oxygen barrier layers, the anti-vibration layer and the anti-crack layer; and
developing and curing the exposed layer of organic material, so as to form the water and oxygen barrier layers, the anti-vibration layers and the first part of the anti-crack layer.

12. The display substrate according to claim 1, wherein the light emitting device comprises: a light emitting layer on the base substrate and a cathode on the light emitting layer.

13. The display substrate according to claim 12, wherein the encapsulating layer comprises: a first inorganic encapsulating layer, an organic encapsulating layer and a second inorganic encapsulating layer sequentially arranged on the cathode.

14. The display substrate according to claim 4, wherein the water and oxygen barrier layers are spaced from the anti-vibration layer at a certain distance.

15. The display substrate according to claim 4, wherein an organic layer is further provided above the water and oxygen barrier layers.

16. The display substrate according to claim 4, wherein the anti-crack layer is located at an edge of the display substrate.

17. The display substrate according to claim 16, wherein a certain burning area for laser cutting is reserved at an outermost edge of the display substrate.

18. The display substrate according to claim 14, wherein the anti-crack layer further includes a first part and a second part, the first part is made of an organic material, and the second part is made of an inorganic material.
